(19) United States
(12) Patent Application Publication
(10) Pub. No.: US 2011/0103023 A1
(43) Pub. Date: May 5, 2011

(54) LOCKING DEVICE AND HEAT DISSIPATION DEVICE USING THE SAME

(75) Inventor: Hao-Der Cheng, Tu-Cheng (TW)

(73) Assignee: HON HAI PRECISION INDUSTRY CO., LTD., Tu-Cheng (TW)

(21) Appl. No.: 12/765,794

(22) Filed: Apr. 22, 2010

(30) Foreign Application Priority Data
Oct. 30, 2009 (CN) 200910309109.2

(51) Int. Cl. H05K 7/20; F28F 9/007

(52) U.S. Cl. 361/720; 165/80.2

(57) ABSTRACT

A heat dissipation device includes a heat sink and locking devices disposed on the heat sink. Each of the locking devices includes a shaft member and an elastic member circling the shaft member. The shaft member includes a body portion, a head portion formed at a top end of the body portion and a foot portion formed at a bottom end of the body portion. The foot portion includes a bucking part having two opposite ends thereof extending beyond the body portion and at least one positioning pole extending towards the head portion from a top surface of the bucking part. The bucking part is located below the heat sink and the elastic member is sandwiched between the head portion of the shaft member and the heat sink.

### BACKGROUND

1. Technical Field

The disclosure relates to heat dissipation devices and, more particularly, to a heat dissipation device having a locking device which secures a heat sink of the heat dissipation device to an electronic component mounted on a printed circuit board.

2. Description of Related Art

It is well known that, during operation of a computer, electronic components such as central processing units (CPUs) frequently generate large amounts of heat. The heat must be quickly removed from the electronic component to prevent it from becoming unstable or being damaged. A heat dissipation device is utilized to dissipate the heat from the electronic component. The heat dissipation device comprises a heat sink attached to an outer face of the electronic component. The heat sink absorbs the heat from the electronic component and dissipates it to ambient air.

In order to keep the heat sink in intimate contact with the electronic component, a locking device is used to secure the heat sink to the electronic component. Referring to FIG. 6, a related-art locking device is shown. The locking device comprises two fasteners 10 for securing a heat sink 20 to an electronic component 40 mounted on a printed circuit board 30. Each fastener 10 comprises a pole 14, a head 12 located at an end of the pole 14, and a plug 16 located at an opposite end of the pole 14. A helical spring 18 circles the pole 14 between the head 12 and the plug 16. The plug 16 forms two barbs at two opposite sides of the plug 16. In use, the plug 16 extends through a hole 24 defined in an ear 22 which extends from a side of the heat sink 20 and a hole 32 defined in the printed circuit board 30. At a bottom side of the printed circuit board 30, the barbs of the plug 16 abut against the printed circuit board 30. The spring 18 is located on the ear 22 of the heat sink 20 and presses the heat sink 20 to the electronic component 40. Therefore, the heat sink 20 is secured to and in contact with the electronic component 40.

However, when detaching the heat sink 20 from the electronic component 40, a tool must be used to turn the barbs of the plug 16 to enter into the hole 32 of the printed circuit board 30 and the hole 24 of the heat sink 20, which is very inconvenient. Otherwise, in order to detach the heat sink 20 from the electronic component 40, the plug 16 must be cut away from the pole 14, which is a waste of material and will increase the cost.

What is needed, therefore, is a heat dissipation device having a locking device which can overcome the above-described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, exploded view of a heat dissipation device in accordance with an embodiment of the disclosure, showing the heat dissipation device ready to be attached on a printed circuit board.

FIG. 2 shows a shaft member of a locking device of the heat dissipation device of FIG. 1.

FIG. 3 is an isometric, assembled view of the heat dissipation device of FIG. 1, wherein the heat dissipation device is secured to the printed circuit board.

FIG. 4 is a partially cutaway view of FIG. 3, taken along line IV-IV thereof, wherein the locking device is in an unlocked state.

FIG. 5 is a partial, sectional view of FIG. 3, taken along line IV-IV thereof, wherein the locking device is in a locked state.

FIG. 6 is an isometric, exploded view of a heat dissipation device of a related art, with a printed circuit board located below the heat dissipation device.

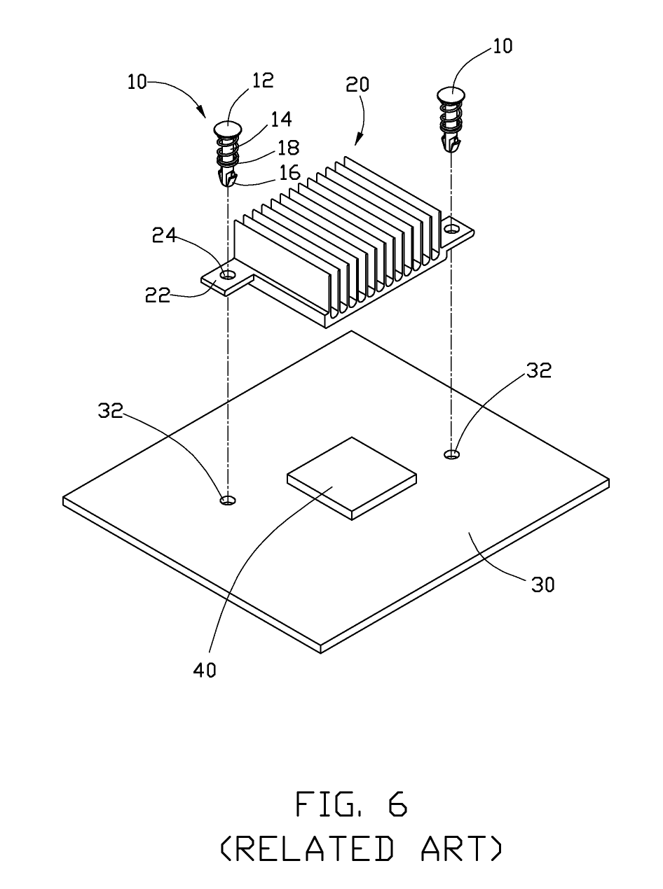

### DETAILED DESCRIPTION

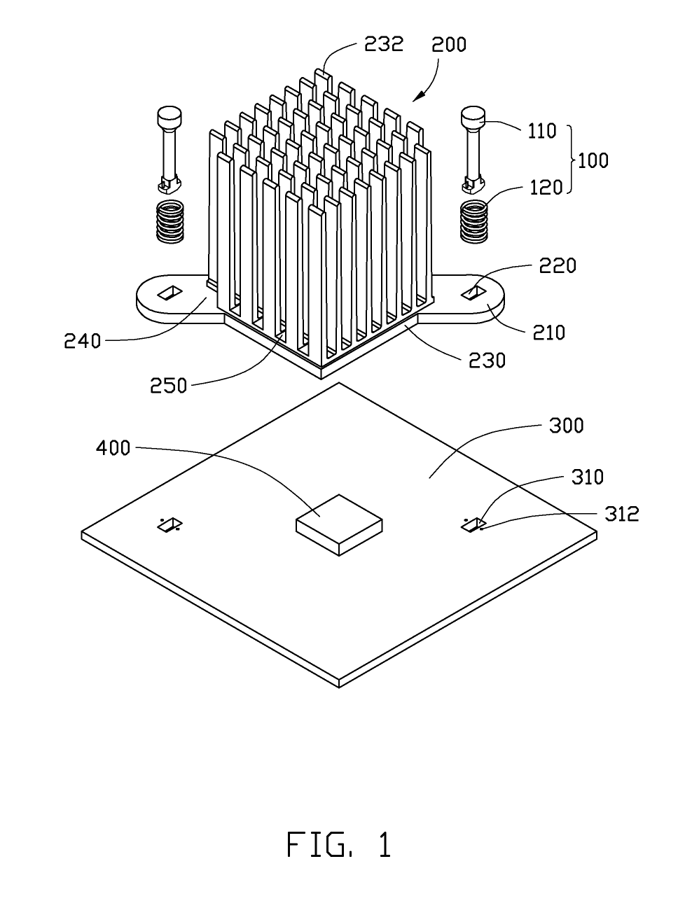

Referring to FIG. 1, an electronic device is illustrated in accordance with an embodiment of the disclosure. The electronic device comprises a printed circuit board (PCB) 300 and a heat dissipation device mounted on the PCB 300. The heat dissipation device dissipates heat generated by an electronic component 400, such as a central processing unit (CPU), mounted on the PCB 300. The heat dissipation device comprises a heat sink 200 and two locking devices 100 securing the heat sink 200 to an outer face of the electronic component 400.

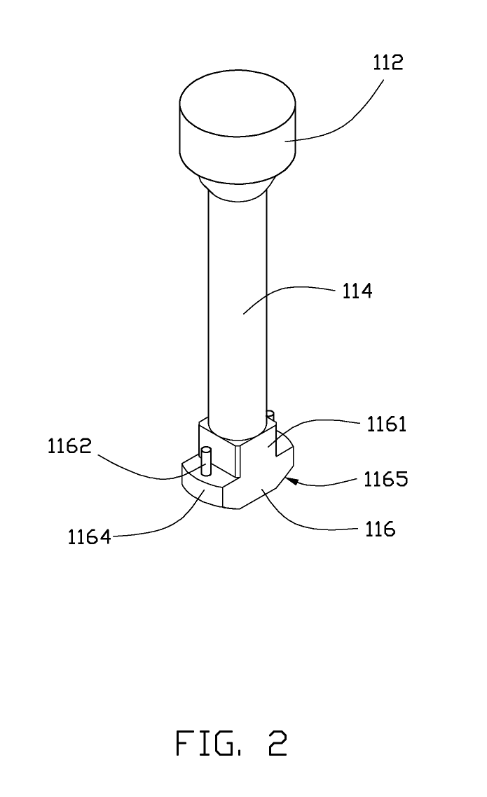

Also referring to FIG. 2, each of the locking devices 100 comprises a shaft member 110 and an elastic member 120 circling the shaft member 110. The shaft member 110 is integrally made of plastic or metal. The shaft member 110 comprises a body portion 114, a head portion 112 formed at a top end of the body portion 114, and a foot portion 116 formed at an opposite bottom end of the body portion 114. In this embodiment, the elastic member 120 is a helical spring. The helical spring is coiled around the body portion 114 between the head portion 112 and the foot portion 116.

In this embodiment, the head portion 112 of the shaft member 110 has a columnar configuration. In other embodiments, the head portion 112 of the shaft member 110 may be elliptical or other shape, so long as the head portion 112 can block the helical spring 120 from escaping from the body portion 114 at the head portion 112.

The foot portion 116 has a T-shaped vertical cross section. The foot portion 116 comprises a square columnar positioning part 1161, a bucking part 1164, and two positioning poles 1162 extending upwardly from a top surface of the bucking part 1164. The positioning part 1161 is located at an end of the body portion 114. The bucking part 1164 has two opposite ends thereof extending beyond the positioning part 1161 and has two opposite sides thereof coplanar with two opposite sides of the positioning part 1161. A horizontal cross section of the bucking part 1164 is rectangular in this embodiment. The bucking part 1164 has a width identical to the width of the positioning part 1161, and a length larger than the width of the bucking part 1164. In other embodiments, the bucking part 1164 may be some other shape, such as elliptical, to make sure that the opposite ends of the bucking part 1164 abut against a bottom of the PCB 300. The foot portion 116 has a bottom end thereof tapered downwardly to form a guiding surface 1165 to facilitate the foot portion 116 extending through the heat sink 200 and the PCB 300. The positioning poles 1162 are located at two opposite sides of the body portion 114 of the shaft member 110, respectively. Each of the positioning poles 1162 is spaced from the positioning part 1161. In other embodiments, only one positioning pole 1162 is disposed at one side of the body portion 114. Alternatively, the positioning pole 1162 may be a wedge. In this embodiment, the positioning parts 1161 are taller than the positioning poles 1162. In other embodiments, the positioning parts 1161 are equal to or shorter than the positioning poles 1162.

The heat sink 200 comprises a base 230 attached to the outer face of the electronic component 400 and a plurality of fins 232 arranged on the base 230. The base 230 extends two ears 210 outwardly from two diagonally opposite corners thereof. The ears 210 extend outwardly beyond the fins 232. Each of the ears 210 defines an extending hole 220 adjacent to a distal end thereof and extending vertically through the ear 210. The extending hole 220 has a shape basically identical to and slightly larger than the foot portion 116, for allowing extension of the foot portion 116 therethrough. The fins 232 are spaced from each other to form a plurality of air passages 250 arranged in a crisscross pattern. The fins 232 define two receiving spaces 240 adjacent to corresponding ears 210 for facilitating operation of the shaft member 110.

The PCB 300 defines two through holes 310 at two sides of the electronic component 400 and corresponding to the extending holes 220 of the heat sink 200. The PCB 300 defines two receiving portions 312 at two opposite sides of each of the through holes 310. The receiving portions 312 correspond to the positioning poles 1162 of the foot portion 116 for receiving the positioning poles 1162 therein. In this embodiment, each of the receiving portions 312 is a receiving hole extending vertically through the PCB 300 for receiving a corresponding positioning pole 1162. In other embodiments, each of the receiving portions 312 may be a blind hole or a groove defined in a bottom surface of the PCB 300. A width of the positioning part 1161 of the foot portion 116 each of the shaft members 110 is slightly less than that of a corresponding through hole 310 defined in the PCB 300 so that the corresponding through hole 310 receives and limits the positioning part 1161 from rotating in a horizontal direction.

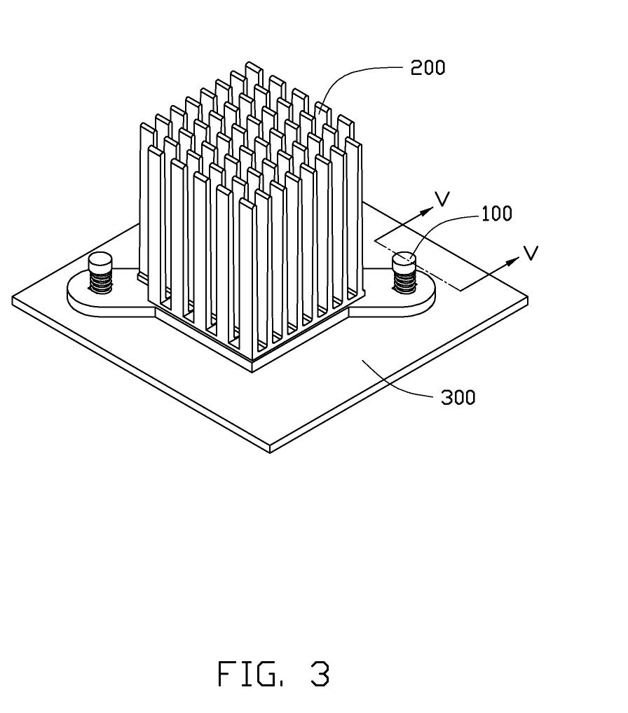

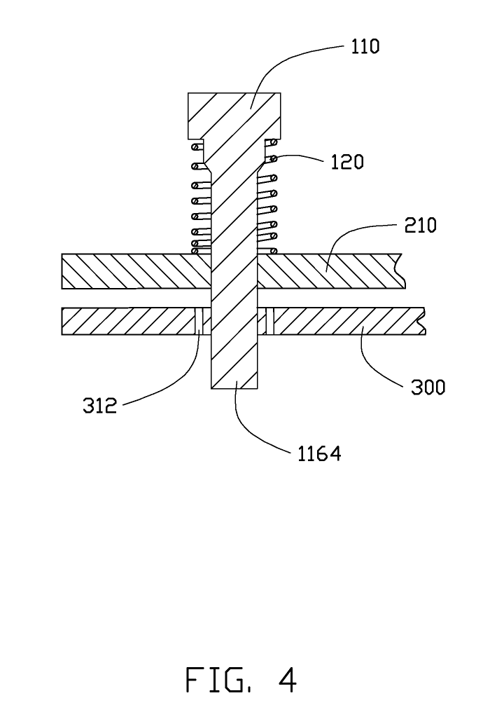

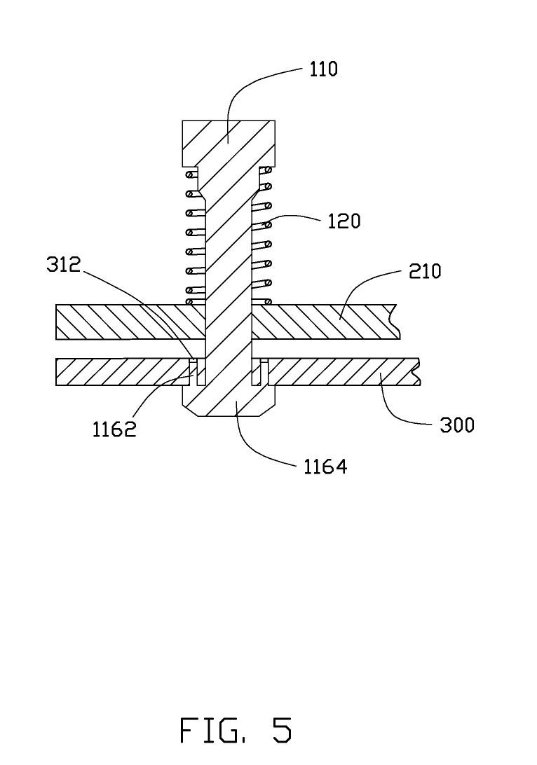

Referring to FIGS. 3-5, when the heat sink 200 is assembled to the electronic component 400, the heat sink 200 is seated on the electronic component 400 and the extending holes 220 thereof are aligned with the through holes 310 of the PCB 300. The shaft members 110 have the foot portions 116 inserted sequentially through the extending holes 220 of the heat sink 200 and the through holes 310 of the PCB 300. The shaft members 110 are pressed in to such an extent that the positioning parts 1161 of the foot portions 116 are located under the bottom surface of the PCB 300. At the same time, the spring 120 is compressed and sandwiched between the head portion 112 of the foot portion 116 and the ear 210 of the heat sink 200; here, the shaft member 110 is located in an unlocked position as shown in FIG. 4. The shaft members 110 are then rotated approximately 90 degrees by operating the head portions 112 of the shaft members 110 to make the positioning poles 1162 fittingly aligned with corresponding receiving portions 312 of the PCB 300. In view of the pressing force on the shaft members 110, the positioning poles 1162 are firmly received in the corresponding receiving portions 312. At the same time, the bucking parts 1164 abut against the bottom surface of the PCB 300; here, the shaft member 110 is located in a locked position as shown in FIG. 5. By this, the heat sink 200 is intimately secured to the electronic component 400.

When removing the heat sink 200 from the electronic component 400, the shaft members 110 are pressed downwardly to make the positioning parts 1161 of the foot portions 116 extend beyond the bottom surface of the PCB 300, and are rotated 90 degrees to make the positioning poles 1162 of the foot portions 116 align with the through holes 310 of the PCB 300. The pressing force on the shaft members 110 is removed, and under a spring force of the springs 120, the foot portions 116 move upwardly to exit the through holes 310 and the extending holes 220 of the heat sink 200; here, the heat sink 200 can be removed from the electronic component 400.

It is convenient to press or lift and then rotate the shaft members 110 in order to assemble or disassemble the heat sink 200 to/from the electronic component 400. The locking devices 100 are reusable. In addition, when the positioning poles 1162 of the shaft members 110 of the locking devices 100 are received in the receiving portions 312 of the PCB 300, and the positioning parts 1161 of the locking devices 100 are received in the through holes 310 of the PCB 300, the shaft members 110 are prevented from rotating relative to the PCB 300.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A locking device for securing a heat sink to a printed circuit board, the locking device comprising:
a shaft member comprising a body portion, a head portion formed at a top end of the body portion and a foot portion formed at a bottom end of the body portion; and
an elastic member circling the body portion between the head portion and the foot portion;
wherein the foot portion comprises a bucking part having two opposite ends thereof extending beyond the body portion and at least one positioning pole extending towards the head portion from a top surface of the bucking part.

2. The locking device of claim 1, wherein the at least one positioning pole of the foot portion is located at a side of the body portion of the shaft member and is spaced from the body portion.

3. The locking device of claim 1, wherein the foot portion further comprises a positioning part connecting the bottom end of the body portion of the shaft member and the bucking part, the at least one positioning pole being spaced from the positioning part.

3. The locking device of claim 1, wherein the at least a positioning pole is columnar or wedge-shaped.

4. A heat dissipation device comprising:
a heat sink; and
a plurality of locking devices disposed on the heat sink, each of the locking devices comprising a shaft member and an elastic member circling the shaft member; the shaft member comprising a body portion, a head portion formed at a top end of the body portion and a foot portion formed at a bottom end of the body portion, the foot portion comprising a bucking part having two opposite ends thereof extending beyond the body portion and at least one positioning pole extending towards the head portion from a top surface of the bucking part, the bucking part being located below the heat sink and the elastic member being sandwiched between the head portion of the shaft member and the heat sink.

5. The heat dissipation device of claim 4, wherein the foot portion further comprises a positioning part connecting the bottom end of the body portion of the shaft member and a central portion of the bucking part, the at least one positioning pole being spaced from the positioning part.

6. The heat dissipation device of claim 4, wherein the at least one positioning pole is columnar or wedge-shaped.

7. An electronic device comprising:
a heat sink;
a printed circuit board;
a plurality of locking devices securing the heat sink to the printed circuit board, each of the locking devices comprising a shaft member and an elastic member circling the shaft member; the shaft member comprising a body portion, a head portion formed at a top end of the body portion and a foot portion formed at a bottom end of the body portion, the foot portion comprising a bucking part having two opposite ends thereof extending beyond the body portion and at least one positioning pole extending towards the head portion from a top surface of the bucking part, the at least one positioning pole being received in the printed circuit board.

8. The electronic device of claim 7, wherein the foot portion further comprises a positioning part connecting the bottom end of the body portion of the shaft member and a central portion of the bucking part, the at least one positioning pole being spaced from the positioning part.

9. The electronic device of claim 7, wherein the at least one positioning pole is columnar or wedge-shaped.

10. The electronic device of claim 7, wherein the printed circuit board defines a plurality of through holes for allowing extension of the foot portions of the shaft members of the locking devices, at least one receiving portion being defined at a side of each of through holes for receiving the at least one positioning pole of the shaft member.
